(19) United States
(12) Patent Application Publication
(10) Pub. No.: US 2005/0156177 A1
(43) Pub. Date: Jul. 21, 2005

(54) Light-emitting device with enlarged area of active luminescence region

(76) Inventors: Ming-Der Lin, Hsinchu (TW); San Bao Lin, Jungli City (TW); Jung-Kuei Hsu, Taipei (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/842,507

(22) Filed: May 11, 2004

(30) Foreign Application Priority Data
Jan. 20, 2004 (TW) 093101497

(51) Int. Cl. H01L 29/26; H01L 31/12; H01L 27/15; H01L 29/267

(52) U.S. Cl. 257/79; 257/81; 257/778; 257/99

(57) ABSTRACT

A light-emitting device is provided, having an enlarged area of active luminescence region to enhance the brightness, mainly comprising a second epitaxy layer and at least one first epitaxy layer provided on a die substrate in turn. On the top surface of the first epitaxy layer, there are provided with at least one first electrode, and a plurality of second electrodes passing through the first epitaxy layer, insulated with the first epitaxy layer by means of an electrode insulation layer, and electrically connected to the second epitaxy layer, in which the first electrode and the second electrodes are alternately arranged. Moreover, first power supply circuits and second power supply circuits are provided on a power supply substrate at positions based on the locations of the first electrode and second electrodes so as to be adhesively electrically connected to the first electrode and the second electrodes, correspondingly. The plurality of first power supply circuits is connectedly provided with a first connective circuit, and the second power supply circuits are connectedly provided with a second connective circuit. The first connective circuit and second connective circuit are provided on the power supply substrate, instead of provided on the light-emitting device directly. Thus, the area of active luminescence region is relatively enlarged, whereby the luminous yield is enhanced accordingly.

### FIELD OF THE INVENTION

The present invention is related to a light-emitting device, particularly to a light-emitting device having an enlarged area of active luminescence region so as to enhance the brightness, essentially providing a first connective circuit and a second connective circuit on a power supply substrate, without occupying the active luminescence region of the light-emitting device directly.

### BACKGROUND

Light-emitting devices (LEDs) have been widely used in computer peripherals, communication products, and other electronic equipments owing to advantages, such as small volume, light weight, lower power consumption, and long service life, as examples. For general mass-produced LEDs, there is grown an epitxy layer with a PN junction on a substrate, made from the material such as sapphire, SiC, and so on. The light may be projected from the PN junction owing to the recombination of electron-hole, when a drive voltage is applied across two sides of the P-type epitaxy layer and the N-type epitaxy layer.

For a conventional LED device, as illustrated in FIGS. 1A and 1B, there are shown a side view and a top view of the structure of conventional LED device. As shown in these figures, there is essentially grown a second epitaxy layer 15 on top of a die substrate 11. On the second epitaxy layer 15, a relatively projecting first surface 153 and a relatively recessed second surface 155 may be defined, in which a first epitxy layer 13 is formed on the first surface 153, such that an active luminescence region (i.e., first surface 153) with the effect of generating a projecting light may be formed between the first epitxy layer 13 and the second epitaxy layer 15 naturally. A part of top surface of the first epitaxy layer 13 is provided with a first electrode 17 thereon, and the second surface 155 of the second epitaxy layer 15, on which none of the first epitaxy layer 13 is presented, is provided with a second electrode 19 thereon. Moreover, a part of top surface of the first electrode 17 is provided with a first bonding pad 171 allowed to be connected to the external circuit, while the top surface of the second electrode 19 is provided with a second bonding pad 191 allowed to be connected to the external circuit. When a forward-biased drive power is introduced via the first electrode 17 and the second electrode 19, the current may be directed into the active luminescence region 153 to operate, and the projecting light may be thus generated.

For a LED, the luminous flux is more, provided that the active area of the active luminescence region 153 is larger; while the luminous intensity is also higher, provided that the current flowing through the active luminescence region 153 is larger. If the current density flowing through the active luminescence region 153 is non-uniform, however, the appearance that the current density flowing through a part of active luminescence region 153 is too high, while the current density flowing through another part of active luminescence region 153 is relatively too low, may easily occur. When the current density flowing through the active illuminescense region 153 is so high to reach the saturation state, not only a reduced luminous yield, but also a locally raised working temperature in the active luminescence region 153, and even the damage may be effected. On the contrary, when the current density flowing through the active luminescence region is so low that the luminous yield could not be fully developed, the area of the element may be wasted. Therefore, how to facilitate the working current to flow through the active luminescence region 153 uniformly for enhancing the luminous yield is truly a significant problem in the fabrication and design for the LED.

It is extremely likely to bring about a non-uniform distribution of current density in the aforementioned structure of diode, however, owing to the geometrically asymmetrical distribution of the first electrode 17 and the second electrode 19. For the purpose of avoiding this non-uniform current density, a structure of LED enabling a uniform distribution of working current has been proposed by the industry. As illustrated in FIGS. 2A and 2B, there are shown a top view and a cross section view, taken along line A-B, of the structure of another conventional LED, respectively. A LED 20 mainly comprises a second epitaxy layer 25 formed on the top surface of a die substrate 21. On the second epitaxy layer 25, a plurality of relatively projecting first surfaces 253 and a plurality of relatively recessed surfaces 255 may be defined, the first surfaces 253 and the second surfaces 255 being arranged alternately, in which a first epitaxy layer 23 is formed on each of the first surfaces 253, such that an active luminescence region (i.e., first surface 253) is formed at the junction between each first epitaxy layer 23 and the second epitaxy layer 25. The top surface of each first epitaxy layer 23 is provided with a first electrode 271, while the top surface of each second surface 255 of the second epitaxy layer 25 is provided with a second electrode 291. Similarly, the first electrodes 271 and the second electrodes 291 are arranged alternately, owing to the locations of the first surfaces 253 and the second surfaces 255. Moreover, there are further provided with a first communicating electrode 273 allowed for communicating the plurality of first electrodes 271 and contacted with the first epitaxy layers 23, as well as a second communicating electrode 293 allowed for electrically communicating the plurality of second electrodes 291 and contacted with the second surfaces 255 of the second epitaxy layer 25 directly, in such a way that the first electrodes 271 may be electrically conducted with each other; for the same reason, the second electrodes 291 may be also electrically conducted with each other. Thus, the non-uniform distribution of the working current density in the active luminescence region 253 may be reduced effectively owing to the considerable symmetry in geometry, resulted from alternate disposition of each first electrode 271 and second electrode 291.

Although the non-uniform distribution of the working current density in the active luminescence region 253 is effectively reduced by the use of aforementioned structure of LED, the zone of the LED 20 occupied by the second surface 255 is enlarged, reducing the active area of the active luminescence region 253, due to the fact that the second communicating electrode 293 is disposed on the second surfaces 255 of the second epitaxy layer 25 alternately, in other words, a part of second surfaces 255 should be further chiseled in order to accommodate the locations where the second communicating electrode 293 is disposed. Thereby, a part of area of the active luminescence region 253 may be occupied by the second communicating electrode 293, resulting in a regret of reducing the light output and brightness correspondingly.

### SUMMARY OF THE INVENTION

For this purpose, how to design a novel light-emitting device with not only a relatively enlarged area of active luminescence region in a LED in order to enhance the brightness, but also an uniform distribution of working current density and thus a prolonged service life, aiming at the disadvantages in the above conventional technology, is the key point of the present invention.

Accordingly, it is the primary object of the present invention to provide a light-emitting device having an enlarged area of active luminescence region comprising a first connective circuit and a second connective circuit, provided on a power supply substrate, allowed for being electrically communicated to a plurality of corresponding first electrodes and second electrodes on a light-emitting diode (LED) die directly in place of a first communicating electrode and a second communicating electrode originally provided on the LED die, in order to avoid an area of the active luminescence region occupied by the first communicating electrode and the second communicating electrode, further resulting in the effect of relatively enhancing the luminous flux and brightness.

It is the secondary object of the present invention to provide a light-emitting device having an enlarged area of active luminescence region comprising a plurality of first electrodes and second electrodes designed such that the structure thereof is presented as geometrical symmetry, whereby the current density in the active luminescence region is uniformly distributed, further leading to an enhanced luminous yield and a prolonged service life of the product.

It is another object of the present invention to provide a light-emitting device having an enlarged area of active luminescence region comprising a pattern of a first power supply circuit and second power supply circuit, provided on a power supply substrate directly, arranged in accordance with the geometrical pattern of a first electrode and second electrode of a LED die, for achieving the object of increasing the package density.

It I still another object of the present invention to provide a light-emitting device having an enlarged area of active luminescence region comprising wire-bonding pads seated on a power supply substrate without performing a wire-bonding process on a LED die directly, the shade for the LED resulted from wire-bonding process may be avoided.

For the purpose of achieving aforementioned objects, the present invention provides a light-emitting device having an enlarged area of active luminescence region, the main structure thereof comprising at least one die light-emitting die, each including a die substrate provided with a second epitaxy layer defining at least one first surface and at least one second surface, the first surface being further formed with a first epitaxy layer thereon, an active luminescence region being naturally formed between the first epitaxy layer and the second epitaxy layer, a part of surface of the first epitaxy layer being provided with at least one first electrode, while a part of the surface of the second epitaxy layer being provided with at least one second electrode; and a power supply substrate provided with, on the surface thereof, at least one first power supply circuit and at least one second power supply circuit at positions corresponding to the first electrode and the second electrode, respectively, each first power supply circuit being electrically connected to another via a first connective circuit, while each second power supply circuit being connected to another via a second connective circuit, the first power supply circuit being electrically interconnected with the corresponding first electrode, while the second power supply circuit being electrically interconnected with the corresponding second electrode.

### BRIEF DESCRIPTION OF DRAWINGS

FIG. 1A is a side view of the structure of a conventional LED;

FIG. 1B a top view of the structure of the conventional LED shown in FIG. 1A;

FIG. 2A is a top view of the structure of another conventional LED;

FIG. 2B is a cross section view of the LED shown in FIG. 2A, taken along line A-B;

FIG. 3A is a top view of the structure of a LED according to one preferred embodiment of the present invention;

FIG. 3B is a cross section view according to the embodiment shown in FIG. 3A, taken alone line C-D;

FIG. 3C is a top view of a power supply substrate in one exemplary embodiment;

FIG. 4A is a top view of an assembled structure of a LED die and a power supply substrate of the present invention;

FIG. 4B is a cross section view according to the embodiment of the present invention shown in FIG. 4A, taken alone line E-F;

FIG. 5A is a disassembled view according to another embodiment of the present invention;

FIG. 5B is an assembled view according to the embodiment of the present invention shown in FIG. 5A;

FIG. 6A is a top view of the structure of a LED die according to another embodiment of the present invention;

FIG. 6B is a cross section view according to the embodiment of the present invention shown in FIG. 6A;

FIG. 6C is a top view of the structure of a power supply substrate according to one preferred embodiment of the present invention;

FIG. 7A is a top view of an assembled structure formed from the structures according to the embodiment of the present invention shown in FIGS. 6A and 6C; and

FIG. 7B is a cross section view according to the embodiment of the present invention shown in FIG. 7A.

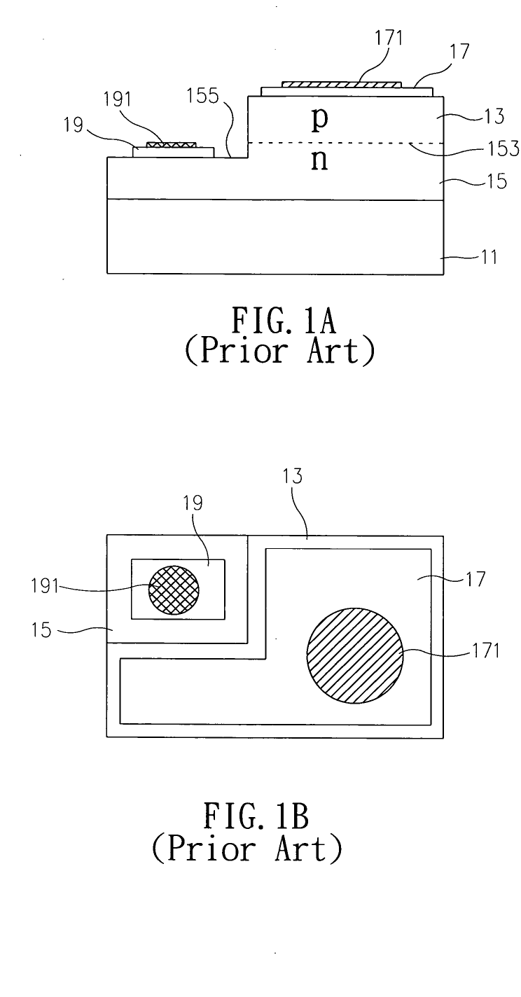

### DETAILED DESCRIPTION

The structural features and the effects to be achieved may further be understood and appreciated by reference to the presently preferred embodiments together with the detailed description.

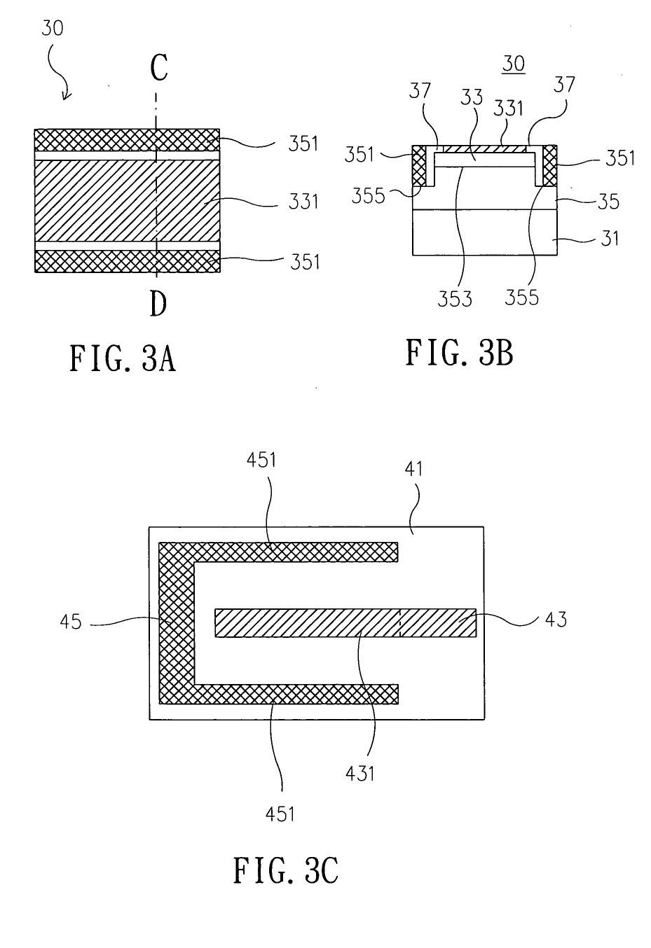

Referring to FIGS. 3A to 3C, firstly, there are shown a top view of the structure according to one preferred embodiment of the present invention, a cross section view taken along line C-D in FIG. 3A, and a top view of the structure of a power supply substrate. As illustrated in these figures, a light-emitting diode (LED) device with an enlarged active luminescence region essentially comprises a LED die 30 and a power supply substrate 41, in which the LED die 30 is mainly formed with, on a die substrate 31, a second epitaxy layer 35 defining a relatively projecting first surface 353 and a relatively recessed second surface 355, and the first surface 353 is further formed with a first epitaxy layer 33 thereon, such that an active luminescence region (i.e., first surface 353) may be formed between the first epitaxy layer 33 and the second epitaxy layer 35 naturally. In general, the die substrate 31 may be composed of the material, such as SiC, GaAs, sapphire, and GaN, as examples. The first epitaxy layer 33 and the second epitaxy layer 35 are composed of group III-V elements, such as GaN, GaP, InGaP, AlGaN, for example.

A first electrode 331 is provided on the top surface of the first epitaxy layer 33, and two second electrodes 351 are disposed at both sides of the first electrodes 331, respectively, such that the second electrodes 351 may be contacted with the second surface 355 of the second epitaxy layer 35 and electrically insulated with the first epitaxy layer 33 and the first electrode 331 by means of an electrode insulation layer. The first electrode 331 and the second electrodes 351 are arranged alternately, in such a way that an uniform active current is allowed to flow through the active luminescence region 353, further resulting in enhancing luminous yield, and avoiding the damage for the active luminescence region 353 due to the local over-current density.

Furthermore, on the top surface of the power supply substrate 41, at least one first power supply circuit 431 and second power supply circuit 451 are provided directly at positions corresponding to the first electrode 331 and second electrode 351, on the LED die 30, respectively. Moreover, there are further provided with a first connective circuit 43 electrically connected to the first power supply circuit 431, and a second connective circuit 45 also electrically connected to each second power supply circuit 451. The number of the first power supply circuit 431 and second power supply circuit 451 is identical to that of the first electrode 331 and second electrode 351. The power supply substrate 41 may be formed from insulation material selected from the group consisting of Si₃N₄, Al₂O₃, AIN, BeO, as well as SiC, Si, GaN covered with dielectric material (SiO₂, TiO₂, Si₃N₄, and so on), as examples.

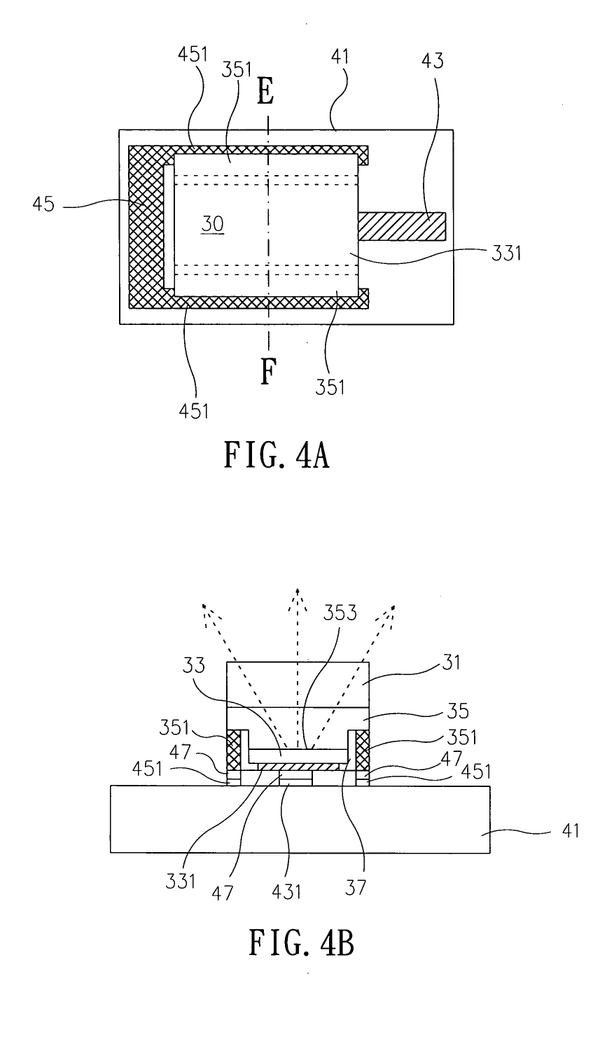

Subsequently, referring to FIGS. 4A and 4B, there are shown a top view of the structure, and a cross section view taken along line E-F in FIG. 4A of the assembled LED die, respectively. As illustrated in these figures, the LED die 30 is inverted, as well as the first electrode 331 and the second electrodes 351 are adhered to the corresponding first power supply circuit 431 and the second power supply circuit 451, respectively, via a bonding layer 47. In this embodiment, the second connective circuit 45 directly provided on the power supply substrate 41 is used to connect with the second electrodes 351 via the plurality of second power supply circuits 451, instead of the fact that a second communicating electrode (293) directly provided on the LED die (20) is used for connecting each second electrode (291) in the conventional structure, in order to avoid an area of the active luminescence region (253) occupied by the second communicating electrode (293), thus increasing the available area of the active luminescence region 253, correspondingly. Moreover, the material of bonding layer 47 may be selected form the group consisting of AuSn, AuSi, PbSb, SnAg, SnInAg, Ag adhesive or solder paste, and so on, such that working heat generated from the active luminescence region 353 may be transmitted via the substrate 41 more easily.

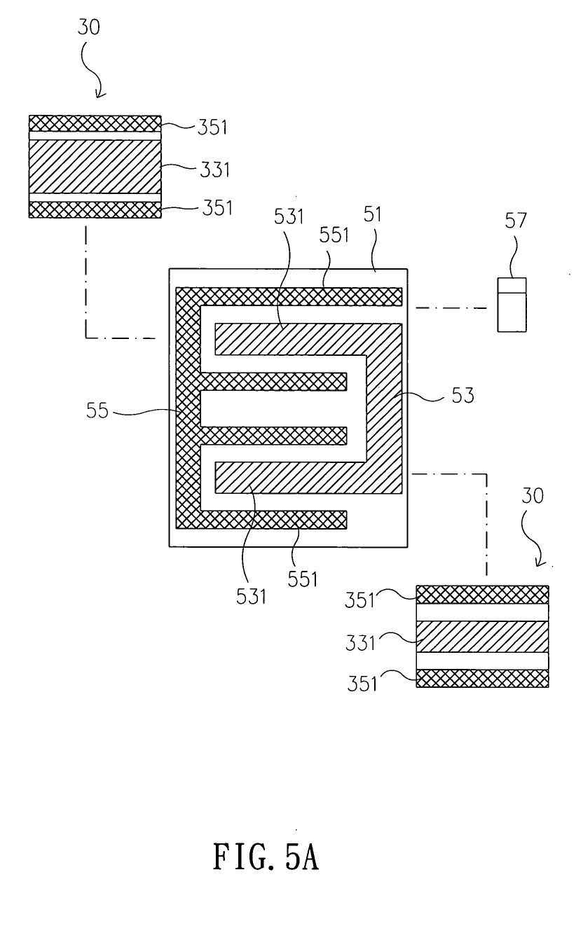

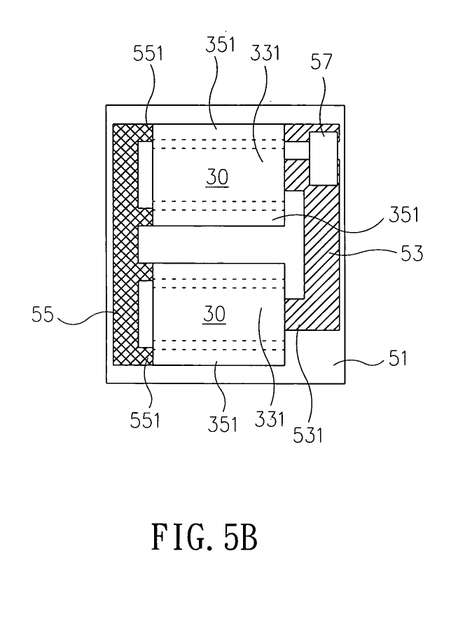

Furthermore, referring to FIGS. 5A and 5B, there are shown a disassembled view and an assembled diagram, according to another embodiment of the present invention. As illustrated in these figures, a power supply substrate 51 is provided with, on the top surface thereof, a first connective circuit 53 further connectedly provided with a plurality of first power supply circuits 531, and a second connective circuit 55 connectedly provided with a plurality of second power supply circuits 551. When the plurality of LED dies 30 is adhered to the power supply substrate 51 thereon, each first electrode 331 and second electrode 351 of the LED die 30 may be adhered to the corresponding first power supply circuit 531 and second power supply circuit 551, respectively, whereby the plurality of LED dies 30 may be provided on the power supply substrate 51, in order to not only enhance the brightness, but also generate a white light source or full-color light source if sources with different colors, such as blue light, green light, and red light, as examples, are selected to compose the plurality of LED dies 30.

Additionally, an electrostatic discharge (ESD) protection device 57, such as Zener diode and Schottky diode, for example, may be further fixedly provided on the substrate 51, and electrically connected, at two electrodes thereof, to each of the first connective circuit 53 and the second power supply circuit 551, or to each of the second connective circuit 55 and the first power supply circuit 531 (not shown), respectively, so as to prevent apprehension for unexpected damage for the LED die 30 resulted from the effect of ESD. Thus, the normal operation for the LED die 30 may be ensured.

The most LED dies 30 may be provided on the substrate 51 with smallest area, since the plurality of first power supply circuits 531 and second power supply circuits 551 on the substrate 51 are established in correspondence with the number of the first electrodes 331 and second electrodes 351 of the LED dies 30. Thereby, the object of raising the package density, and thus light, thin, short, as well as small light-emitting device may be further obtained.

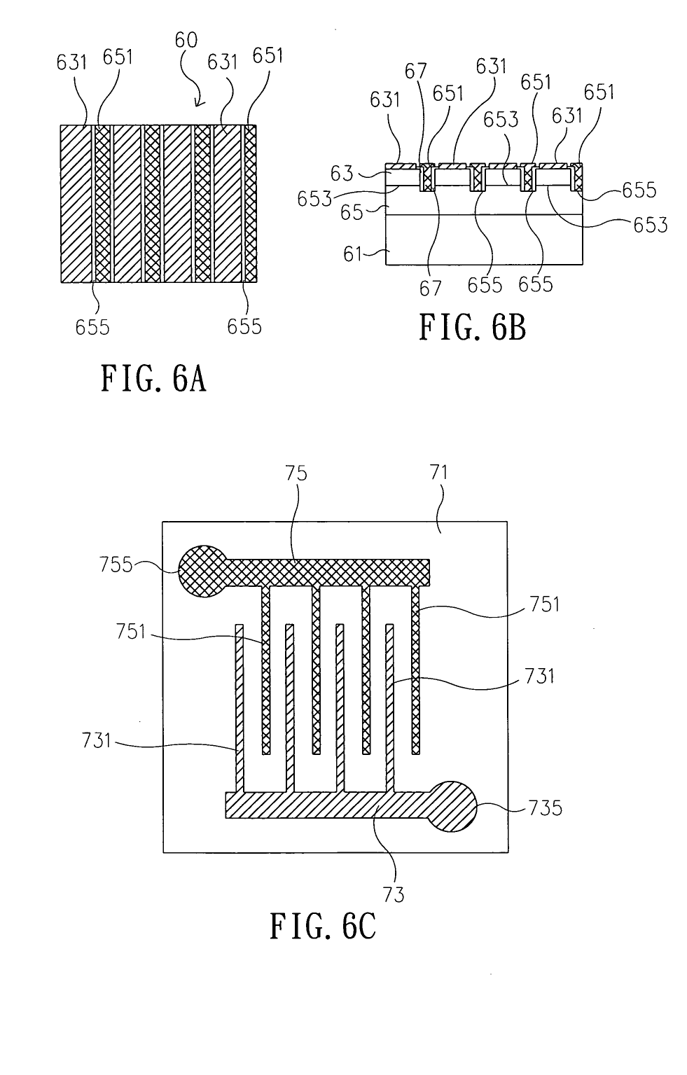

Furthermore, referring to FIGS. 6A to 6C, there are shown a top view, a cross section view of the structure of a LED die, and a top view of the structure of a power supply substrate, respectively, according to still another embodiment of the present invention. As illustrated in these figures, the main structure of a LED die 60 comprises a die substrate 61 provided with, on the surface thereof, a second epitaxy layer 65 defining a plurality of relatively projecting first surfaces 653 and a plurality of relatively recessed second surfaces 655. Each first surface 653 is provided with one first epitaxy layer 63 thereon, such that an active luminescence region (i.e., first surface 653) may be formed between each first epitaxy layer 63 and the second epitaxy layer 65 naturally. Each first epitaxy layer 63 is formed with one first electrode 631 on the top surface thereof, while the second epitaxy layer 65 is formed with a plurality of second electrodes 651 on the second surfaces 655 thereof, in such a way that the first electrodes 631 and second electrodes 651 may be established alternately. Moreover, on the peripheral of each second electrode 651, there is provided with an electrode insulation layer 67 to avoid the direct contact between the second electrode 651 and the first epitaxy layer 63, as well as the first electrode 631.

On a power supply substrate 71, there are provided with a first connective circuit 73, further connectedly provided with a plurality of first power supply circuits 731; and a second connective circuit 75, connected with a plurality of second power supply circuits 751, in which the locations and the number of the plurality of first circuits 731 and second circuits 751 are both in correspondence with those of the first electrodes 631 and second electrodes 651.

Further, a first bonding pad 731, provided on the first connective circuit 73 in place, and a second bonding pad 755, also provided on the second connective circuit 75 in place, are used for wire-bonding process. The direct damage for the LED die 60 resulted from wire-bonding process may be avoided, because the first bonding pad 735 and the second bonding pad 755 are provided on the power supply substrate 71, instead of being provided on the LED die 60 directly. Thereby, the normal operation for the LED die 60 may be protected.

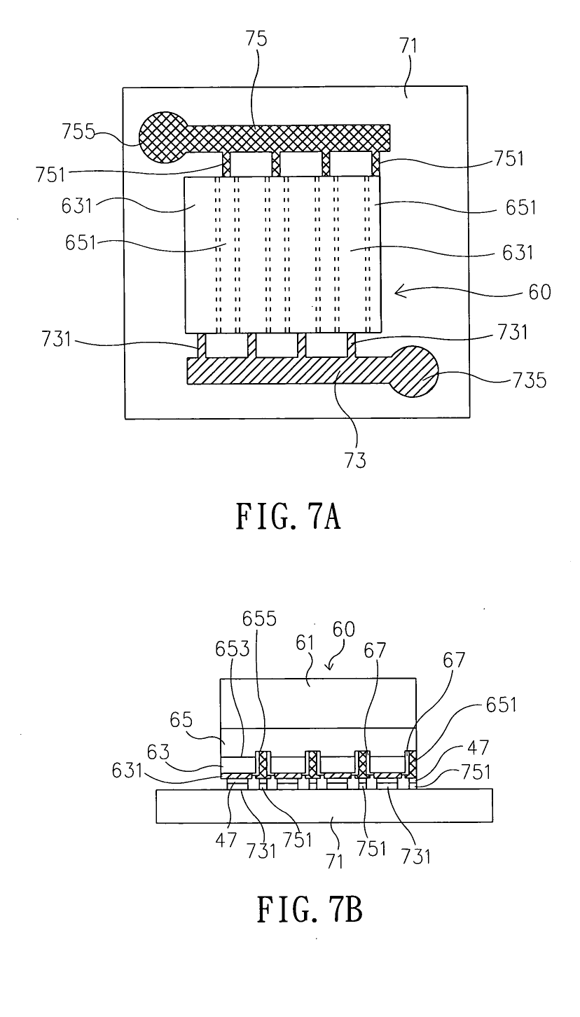

Finally, referring to FIGS. 7A and 7B, there are shown a top view and a cross section view of an assembled structure formed from the structures according to the embodiment shown in FIGS. 6A and 6C. As illustrated in these figures, the LED die 60 is inverted and then adhered to the power supply substrate 71 thereon, such that the plurality of first electrodes 631 may be connected to the corresponding first power supply circuits 731, while the plurality of second electrodes 651 my be connected to the corresponding second power supply circuits 751, respectively.

The working current density in each active luminescence region 653 is extremely uniform, due to the symmetry resulted from the alternating establishment of the first electrodes 631 and second electrodes 651. Moreover, the second electrodes 651 are conducted with each other via the second connective circuit 75 on the power supply substrate 71. Therefore, differently from the conventional structure, apprehension for occupying the area of the active luminescence region (235) which, provided on the LED die (20), is required for connecting individual second electrodes (291), may be eliminated.

Furthermore, the present invention is described with the second electrode presented as linear arrangement in the above embodiments, but is not limited thereto. The annular arrangement, staggered arrangement, and other symmetrically geometrical arrangements are also used for the second electrode, only providing the first connective circuit 73 and the second connective circuit 75 onto the power supply substrate 71, instead of onto the LED die 60 directly, is required. Thus, the effect of enlarging the active luminescence area may be then achieved.

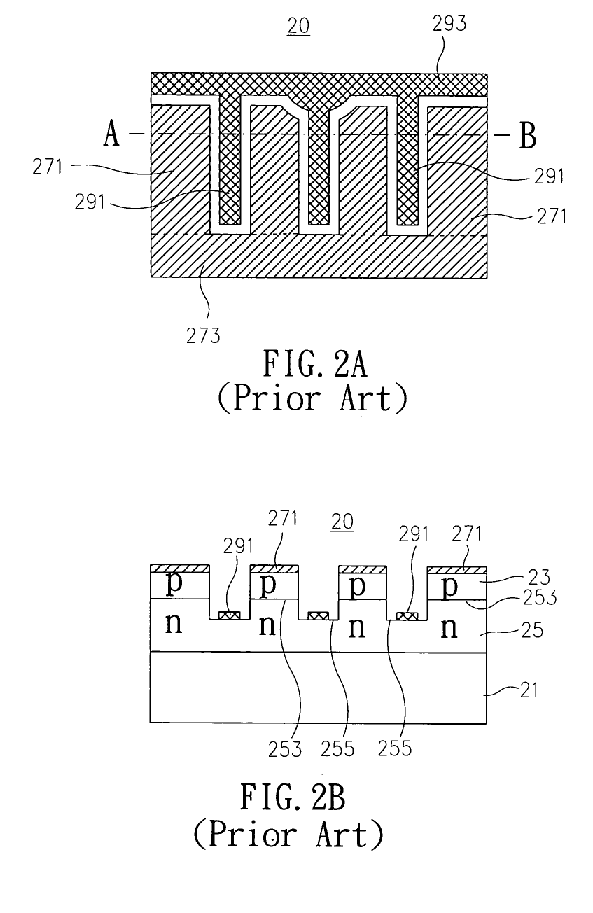

Furthermore, although the second electrodes 351, 651 of the LED dies 30, 60 are designed as being disposed in a horizontal level approximate to or the same as that in which the first electrodes 331, 631 are disposed, respectively, the conventional LED die (20) shown in FIG. 2B is also applicable according to the technical feature of the present invention, only providing the second connective circuit (293) onto the power supply circuit 41 is needed. Thus, the effect intended to be achieved in the present invention is equally attainable.

Furthermore, although the power supply substrates 41, 51, 71 are made from an insulation material in the aforementioned embodiments, other materials such as SiS, Si, and GaAs, as examples, may be substitutively used in different embodiments, only of insulation material further covering these power supply substrates is required.

To sum up, it should be understood that the present invention is related to a light-emitting device, particularly to a light-emitting device having an enlarged area of active luminescence region so as to enhance the brightness, allowed for a relatively enlarged area of active luminescence region, and thus an enhanced luminous yield.

The foregoing description is merely one embodiment of present invention and not considered as restrictive. All equivalent variations and modifications in process, method, feature, and spirit in accordance with the appended claims may be made without in any way from the scope of the invention.

### LIST OF REFERENCE SYMBOLS

11 die substrate
13 first epitaxy layer
15 second epitaxy layer
153 first surface
155 second surface
17 first electrode
19 second electrode
171 first bonding pad
191 second bonding pad
20 light-emitting diode
21 die substrate
23 first epitaxy layer
25 second epitaxy layer
253 first surface
255 second surface
271 first electrode
273 first communicating electrode
291 second electrode
293 second communicating electrode
30 light-emitting diode die
31 die substrate
33 first epitaxy layer
331 first electrode
35 second epitaxy layer
351 second electrode
353 first surface
355 second surface
37 electrode insulation layer
41 power supply substrate
43 first connective circuit
431 first power supply circuit
45 second connective circuit
451 second power supply circuit
47 bonding layer
51 power supply substrate
53 first connective circuit
531 first power supply circuit
55 second connective circuit
551 second power supply circuit
57 electrostatic protecting device
60 light-emitting diode die
61 die substrate
63 first epitaxy layer
631 first electrode
65 second epitaxy layer
651 second electrode
653 first surface
655 second surface
67 electrode insulation layer
71 power supply substrate
73 first connective circuit
731 first power supply circuit
735 first bonding pad
75 second connective circuit
755 second bonding pad
751 second power supply circuit

1. A light-emitting device with enlarged area of active luminescence region, comprising:
at least one light-emitting die, each including a die substrate provided with a second epitaxy layer defining at least one first surface and at least one second surface, said first surface further formed with a first epitaxy layer thereon, an active luminescence region naturally formed between said first epitaxy layer and said second epitaxy layer, a part of surface of said first epitaxy layer provided with at least one first electrode, while a part of surface of said second epitaxy layer provided with at least one second electrode; and
a power supply substrate provided with, on the surface thereof, at least one first power supply circuit and at least one second power supply circuit at positions corresponding to said first electrode and said second electrode, respectively, each of said first power supply circuits electrically connected to another via a first connective circuit, while each of said second power supply circuits connected to another via a second connective circuit, said first power supply circuit electrically interconnected with said corresponding first electrode, while said second power supply circuit electrically interconnected with said corresponding second electrode.

2. The light-emitting device according to claim 1, wherein said power supply substrate is a surface insulation substrate.

3. The light-emitting device according to claim 2, wherein said power supply substrate is made from what selected from the group consisting of Si₃N₄, AIN, SiC, GaN, and the combination thereof.

4. The light-emitting device according to claim 1, wherein said light-emitting diode die is presented as a flip-chip package so as to be inverted and then adhered to said power supply substrate.

5. The light-emitting device according to claim 1, further comprising an electrostatic discharge protection device fixedly provided on said power supply substrate and electrically connected to said first connective circuit and said second power supply circuit, respectively.

6. The light-emitting device according to claim 5, wherein said electrostatic discharge protection device is selected from either Zener diode or Schottky diode.

7. The light-emitting device according to claim 1, further comprising an electrostatic discharge protection device fixedly provided on said power supply substrate and electrically connected to said second connective circuit and said first power supply circuit, respectively.

8. The light-emitting device according to claim 1, wherein said die substrate is made from what selected from the group consisting of SiC, GaN, sapphire, GaAs, and the combination thereof.

9. The light-emitting device according to claim 1, wherein said plurality of second electrodes are presented as what selected from linear arrangement, annular arrangement, staggered arrangement, and the combination thereof.

10. The light-emitting device according to claim 1, wherein said second electrode is provided with an electrode insulation layer at sides thereof.

11. The light-emitting device according to claim 1, wherein the location of said second surface is lower than that of said first surface in said second epitaxy layer.

12. The light-emitting device according to claim 1, wherein said first connective circuit is provided with at least one first bonding pad thereon, while said second connective circuit is provided with at least one second bonding pad thereon.

13. The light-emitting device according to claim 1, wherein a bonding layer is further provided between said first electrode and said first power supply circuit, as well as between said second electrode and said second power supply circuit.
